(19) United States
(12) Patent Application Publication
(10) Pub. No.: US 2011/0306188 A1
(43) Pub. Date: Dec. 15, 2011

(54) MANUFACTURING METHOD OF SILICON CARBIDE SEMICONDUCTOR DEVICE

(75) Inventors: Jun KAWAI, Anjo-city (JP); Nobuyuki KATO, Nisshin-city (JP); Kazuhiro TSURUTA, Nishio-city (JP)

(73) Assignee: DENSO CORPORATION, Kariya-city (JP)

(21) Appl. No.: 13/155,662

(22) Filed: Jun. 8, 2011

(30) Foreign Application Priority Data
Jun. 14, 2010 (JP) 2010-135409

(51) Int. Cl. H01L 21/20

(52) U.S. Cl. 438/482; 257/E21.09

(57) ABSTRACT

In a manufacturing method of a silicon carbide semiconductor device, a semiconductor substrate made of single crystal silicon carbide is prepared, an amorphous layer is formed on a portion of the semiconductor substrate where an electrode is to be formed, a metal layer is formed on the amorphous layer, and the electrode including the metal layer and a silicide layer is formed by irradiating the metal layer with a laser light in such a manner that a part of the metal layer reacts with the amorphous layer and forms the silicide layer.

### CROSS REFERENCE TO RELATED APPLICATIONS

The present application is based on and claims priority to Japanese Patent Application No. 2010-135409 filed on Jun. 14, 2010, the contents of which are incorporated in their entirety herein by reference.

### BACKGROUND OF THE INVENTION

1. Field of the Invention

The present invention relates to a manufacturing method of a silicon carbide (SiC) semiconductor device in which an electrode forms an ohmic junction with a substrate made of silicon carbide.

2. Description of the Related Art

Conventionally, in a case where a vertical power device is formed in a SiC substrate, when an electrode, especially a drain electrode, for coupling the device with an electric circuit is formed, it is desired to form an ohmic electrode so that a contact resistance between the SiC substrate and the drain electrode is reduced.

A method of manufacturing an SiC semiconductor device including an ohmic electrode is disclosed, for example, in Imai et al., “N-type and p-type ohmic contacts for 4H—SiC using Ni salicide process”, 29p-ZM-14, proceedings of the 51st Meeting, the Japan Society of Applied Physics and Related Societies, Mar. 28, 2004. In the manufacturing method, a nickel (Ni) silicide layer is formed on the SiC substrate by a silicide process in order to form an ohmic electrode that has a low resistance contact (a low potential barrier) with both of n type SiC and p type SiC. The silicide process includes performing vacuum evaporation of Ni on the SiC substrate and then performing a thermal treatment of the SiC substrate. In the above-described method, Ni is used as a material of the ohmic electrode, and a sintering process at 800° C. or over is required for forming Ni silicide, which is a compound of Ni and Si, in SiC.

JP-A-2004-158702 discloses a method that includes forming an impurity-doped layer on a SiC substrate, forming a metal layer on the impurity-doped layer, and irradiating the metal layer with a laser light to form an ohmic electrode.

Specifically, after forming an electrode on a front surface of the SiC substrate, the electrode on the front surface is protected with a resin layer. Then, a thickness of the SiC substrate is reduced from a rear surface, and impurity ions are implanted into the rear surface of the SiC substrate. After activating the impurities by a high-temperature heat treatment, the metal layer as an electrode is formed on the rear surface of the SiC substrate. The metal layer is irradiated with the laser light, and thereby the ohmic electrode is formed.

In the method disclosed in JP-A-2004-158702, an impurity-doped layer is formed on the rear surface of the SiC substrate before irradiating the rear surface with the laser light. In order to activate the impurities in the impurity-doped layer, a heat treatment of the SiC substrate at a relatively high temperature is required after forming the impurity-doped layer. In an ion implantation method, a heat treatment of the SiC substrate is performed, for example, at a temperature of from 1600° C. to 1700° C.

Thus, in the above-described methods, the electrode on the front surface of the SiC substrate may be damaged during the heat treatment, and various failure may occur in a device.

In a device in which electric current flows in a front-rear direction such as a vertical power device, it is preferable that a thickness of a SiC substrate is reduced for reducing an operation resistance. However, when the thickness of the SiC substrate is too small, it is difficult to perform a high-temperature heat treatment of the SiC substrate and to form an ohmic electrode on the rear surface of the SiC substrate.

As a method of activating an impurity-doped layer without a high-temperature heat treatment, JP-A-2002-289550 discloses a method of irradiating an SiC substrate with a laser light. A process of forming a rear electrode by the above-described method will be described below.

First, an electrode is formed on a front surface of a SiC substrate in which a vertical device is formed. Next, the front surface of the SiC substrate is protected with a resin layer, and a thickness of the SiC substrate is reduced from a rear surface of the SiC substrate. Then, impurity ions are implanted into the rear surface of the SiC substrate, and the rear surface is irradiated with the laser light. After that, a metal layer is formed on the rear surface of the SiC substrate.

As a method not using an ion implantation process, JP-A-2008-135611 discloses a method of forming a metal layer on a SiC substrate and irradiating the SiC substrate with a laser light. A process of forming a rear electrode by the above-described method will be described below.

First, an electrode is formed on a front surface of a SiC substrate in which a vertical device is formed. Next, the front surface of the SiC substrate is protected with a resin layer, and a thickness of the SiC substrate is reduced from a rear surface of the SiC substrate. Then, a metal layer is formed on the rear surface of the SiC substrate. In a case where the SiC substrate is made of 6H—SiC, the metal layer is irradiated with a laser light of about 2.8 J/cm². In a case where the SiC substrate is made of 4H—SiC, the metal layer is irradiated with a laser light of about 4.2 J/cm². After that, an electrode is formed by forming a metal layer on the rear surface of the SiC substrate.

However, an activation efficiency of an impurity-doped layer in SiC is lower than an activation efficiency of an impurity-doped layer in Si. In order to form an ohmic electrode having a low resistance, it is required that an impurity doped layer having an impurity concentration of greater than or equal to 1×10²⁰ cm⁻³ is formed by ion implantation. On the other hand, when the impurity concentration is increased, an annealing process may not recover disarrangement of crystallinity due to damage by ion implantation. Thus, it is preferable that an ohmic electrode is formed without using an impurity-doped layer. According to an experiment by the inventors, in a case where a metal layer is formed on a rear surface of an SiC substrate and the metal layer is irradiated with a laser light, abrasion or fusion may occur in the rear surface of the SiC substrate if an laser output of the laser light is greater than or equal to 2 J/cm².

### SUMMARY OF THE INVENTION

In view of the foregoing problems, it is an object of the present invention to provide a manufacturing method of a silicon carbide semiconductor device in which an ohmic electrode can be formed at a low temperature process without forming an impurity-doped layer having a high impurity concentration by ion implantation.

In a manufacturing method of a silicon carbide semiconductor device according to an aspect of the present invention, a semiconductor substrate made of single crystal silicon carbide is prepared, an amorphous layer is formed on a portion of the semiconductor substrate where an electrode is to be formed, a metal layer is formed on the amorphous layer, and the electrode including the metal layer and a silicide layer is formed by irradiating the metal layer with a laser light in such a manner that a part of the metal layer reacts with the amorphous layer and forms the silicide layer.

By the above-described method, the electrode can be formed as an ohmic electrode at a low temperature process without forming an impurity-doped layer having a high impurity concentration by ion implantation.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view of a vertical power MOSFET in a SIC semiconductor device manufactured by a method according to a first embodiment;

FIG. 2A to FIG. 2D are diagrams showing processes of forming a drain electrode of the SiC semiconductor device shown in FIG. 1;

FIG. 3 is a graph showing a relationship between a thickness of an amorphous layer and a resistance;

FIG. 4 is a graph showing a relationship between a laser output and a resistance;

FIG. 5 is a graph showing a relationship between a laser energy and a resistance;

FIG. 6A is a diagram showing a result of an Auger analysis in a case where a drain electrode is formed without an amorphous layer and FIG. 6B is a diagram showing a result of an Auger analysis in a case where a drain electrode is formed with an amorphous layer;

FIG. 7A is a cross-sectional TEM image of a sample in the process shown in FIG. 2A and FIG. 7B is a cross-sectional TEM image of a sample in the process shown in FIG. 2D; and

FIG. 8A is an illustrative view of the TEM image shown in FIG. 7A and FIG. 8B is an illustrative view of the TEM image shown in FIG. 7B.

### DETAILED DESCRIPTION OF THE PREFERRED EMBODIMENTS

### First Embodiment

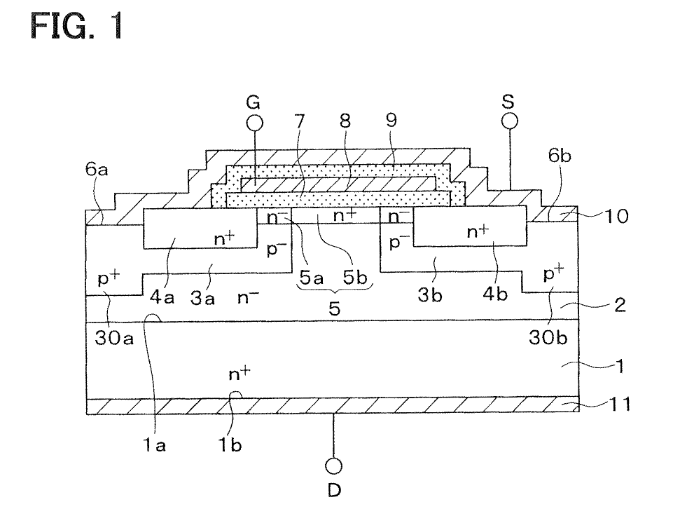

A manufacturing method of a SiC semiconductor device according to a first embodiment will be described below. The SiC semiconductor device manufactured by the method according to the present embodiment includes a planar MOSFET (vertical power MOSFET) as shown in FIG. 1. The SiC semiconductor device can be suitably used for an inverter. A structure of the vertical power MOSFET will be described with reference to FIG. 1.

The vertical power MOSFET includes an n+ type substrate 1. The n+ type substrate 1 has a front surface 1a and a rear surface 1b opposite to each other. The n+ type substrate 1 is made of single crystal SiC. The n+ type substrate 1 has a thickness of, for example, 350 μm. The n+ type substrate 1 has an impurity concentration of, for example, from 1×10¹⁷ cm⁻³ to 1×10¹⁸ cm⁻³. On the front surface 1a of the n+ type substrate 1, an n− type epitaxial layer 2 is disposed. The n− type epitaxial layer 2 is made of SiC and has a lower impurity concentration than the n+ type substrate 1.

At predetermined regions of a surface portion of the n− type epitaxial layer 2, a p− type base region 3a and a p− type base region 3b are disposed so as to be separated from each other. The p− type base region 3a includes a deep base layer 30a that is thicker than other portion of the p− type base region 3a. The p− type base region 3b includes a deep base layer 30b that is thicker than other portion of the p− type base region 3b. An impurity concentration of the deep base layers 30a and 30b is higher than an impurity concentration of the other portions of the p− type base regions 3a and 3b.

By providing the deep base layers 30a and 30b, a thickness of the n− type epitaxial layer 2 under the deep base layers 30a and 30b is reduced, and a distance between the n+ type substrate 1 and the deep base layers 30a and 30b is reduced. Thus, an electric field strength can be increased and an avalanche breakdown can easily occur.

At a predetermined region in a surface portion of the p− type base region 3a, an n+ type source region 4a is disposed. The n+ type source region 4a is shallower than the p− type base region 3a and does not overlap the deep base layer 30a. At a predetermined region in a surface portion of the p− type base region 3b, an n+ type source region 4b is disposed. The n+ type source region 4b is shallower than the p− type base region 3b and does not overlap the deep base layer 30b.

At the surface portions of the p− type base regions 3a and 3b, a surface channel layer 5 made of SiC is disposed. The surface channel layer 5 connects the n+ type source regions 4a, 4b and the n− type epitaxial layer 2. The surface channel layer 5 includes an n− type layer 5a and an n+ type layer 5b. The surface channel layer 5 can function as a channel forming layer on a device surface when a device is in operation.

In the surface channel layer 5, the n− type layer 5a disposed above the p-type base regions 3a, 3b has an impurity concentration of, for example, from 1×10¹⁵ cm⁻³ to 1×10¹⁷ cm³. The impurity concentration of the n− type layer 5a is lower than the impurity concentrations of n− type epitaxial layer 2 and the p− type base regions 3a, 3b. Accordingly, an on-resistance can be reduced.

At surface portions of the p− type base region 3a and the n+ type source region 4a, a depressed portion 6a is provided. At surface portions of the p− type base region 3b and the n+ type source region 4b, a depressed portion 6b is provided.

On surfaces of the surface channel layer 5 and the n+ type source regions 4a, 4b, a gate insulating layer 7 made of silicon oxide is disposed. On the gate insulating layer 7, a gate electrode 8 is disposed. The gate electrode 8 is covered with an insulating layer 9. The insulating layer 9 is made of silicon oxide. On a surface of the insulating layer 9, a source electrode 10 is disposed. The source electrode 10 is in contact with the n+ type source regions 4a, 4b and the p− type base regions 3a, 3b. On the rear surface 1b of the n+ type substrate 1, a drain electrode 11 is disposed. The drain electrode 11 forms an ohmic junction with the rear surface 1b of the n+ type substrate 1.

In the n− type epitaxial layer 2, a portion between the p− type base regions 3a, 3b forms a so-called J-FET part.

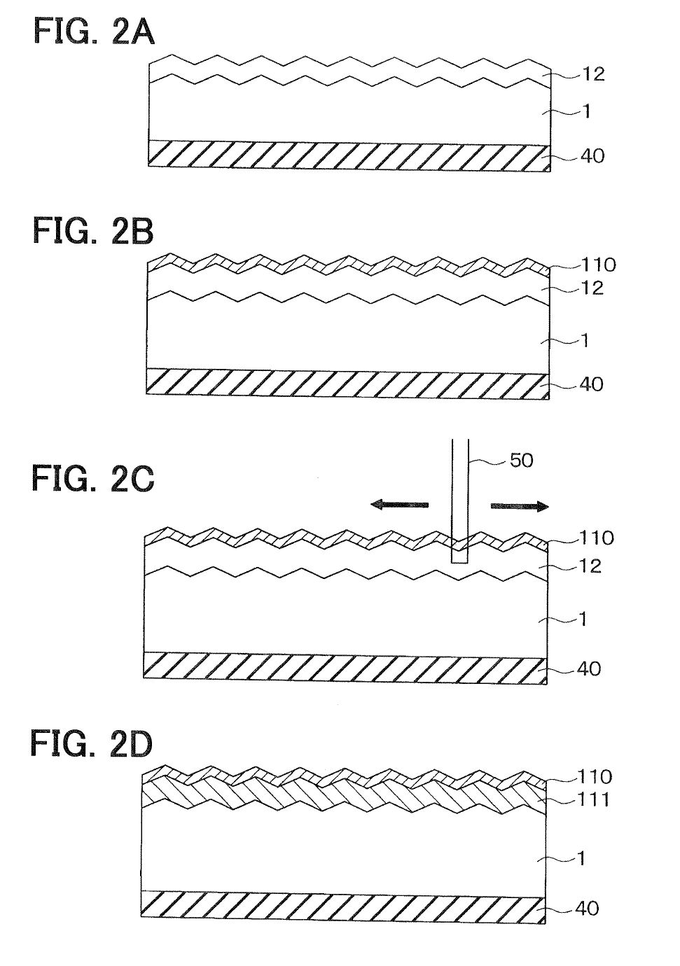

Next, a manufacturing method of the vertical power MOSFET shown in FIG. 1 will be described. Most processes of the manufacturing method of the vertical power MOSFET according to the present embodiment are similar to those of a conventional manufacturing method. Therefore, only a process of forming the drain electrode 11 that is different from the conventional manufacturing method will be described with reference to FIG. 2A to FIG. 2D.

FIG. 2A to FIG. 2D are diagrams showing processes of forming the drain electrode 11 in the vertical power MOSFET shown in FIG. 1. In FIG. 2A to FIG. 2D, an element structure of the vertical power MOSFET is not illustrated for the sake of simplification.

First, the n+ type substrate 1 is prepared. On the front surface side of the n+ type substrate 1, components of the vertical power MOSFET shown in FIG. 1 except for the drain electrode 11 are previously formed.

Then, a process shown in FIG. 2A is performed. The thickness of the n+ type substrate 1 is reduced, for example, to about 350 μm. A protective layer 40 that covers the source electrode 10 is formed on the front surface 1a of the n+ type substrate 1. The protective layer 40 is provided for protecting electrodes formed on the front surface 1a of the n+ type substrate 1 such as the source electrode 10. The protective layer 40 is made of, for example, resin such as polyimide. The front surface side of the n+ type substrate 1 is fixed by the protective layer 40. Then, the drain electrode 11 is formed on the rear surface 1b of the n+ type substrate 1 by the following processes.

On the rear surface 1b of the n+ type substrate 1, an amorphous layer 12 is formed. In the present embodiment, grinding is employed as a forming method. For example, the amorphous layer 12 can be formed by planar grinding with a grinding machine of #600. By the grinding, a crystallinity of the rear surface 1b of the n+ type substrate 1 is disarranged, and thereby the amorphous layer 12 is formed. The amorphous layer 12 on the rear surface 1b of the n+ type substrate 1 has a thickness of from 10 nm to 800 nm. By the planar grinding with the grinding machine of #600, the amorphous layer 12 can have a thickness of about 200 nm. A reason for setting the thickness of the amorphous layer 12 as described above will be described later.

In the process shown in FIG. 2B, a metal layer 110 is formed on the amorphous layer 12. The metal layer 110 is formed, for example, by evaporating Ni above the rear surface 1b of the n+ type substrate 1. A thickness of the metal layer 110 is determined in accordance with the thickness of the amorphous layer 12. The amount of the metal layer 110 that reacts with the amorphous layer 12 increases with the thickness of the amorphous layer 12. Thus, the thickness of the metal layer 110 is determined so that a part of the metal layer 110 remains after reacting with the amorphous layer 12. The metal layer 110 is formed, for example, with a CVD apparatus or a sputtering apparatus. An available thickness of the metal layer 100 depends on an apparatus and a thickness of greater than or equal to 10 nm can be achieved. In a case where the amorphous layer 12 has a thickness of from 10 nm to 800 nm, the thickness of the metal layer 110 is set to be greater than or equal to 10 nm. Such thickness can be achieved with the CVD apparatus or the sputtering apparatus.

In a process shown in FIG. 2C, the metal layer 110 is irradiated with a laser light. For example, an LD excited solid state laser having a fundamental wavelength of 1064 nm is employed. The rear surface 1b is scanned by the laser light 50 of the LD excited solid state laser and only a portion where the metal layer 110 is formed is irradiated with the laser light 50 by a scanning method or a masking method. Accordingly, metal (Ni in the present embodiment) in the metal layer 110 reacts with Si in the n+ type substrate 1 and a silicide layer 111 shown in FIG. 2D is formed. At this time, a product of a photon energy of and a laser output of the LD excited solid state laser, that is, a laser energy of the LD excited solid state laser is set to be from 1000 eV·mJ/cm² to 8000 eV·mJ/cm². The reason of the above-described setting will be described later.

Through the above-described processes, the vertical power MOSFET shown in FIG. 1 is manufactured, and the drain electrode 11 including the silicide layer 111 can be formed. Thus, the drain electrode 11 can be formed as an ohmic electrode by a low-temperature process without using an impurity-doped layer.

The reason of setting the thickness of the amorphous layer 12 and the laser energy (i.e., the product of the photon energy and the laser output of the laser light) to the above-described values will be described below.

First, the process of forming the amorphous layer 12 shown in FIG. 2A will be described. In an experiment by the inventors, the thickness of the amorphous layer 12 is set to be 0.5 nm, 1 nm, 8 nm, 50 nm, or 200 nm, the metal layer 110 is formed on the amorphous layer 12, the metal layer 110 is irradiated with the laser light as shown in FIG. 2C, and thereby the drain electrode 11 is formed. Then, a resistance of each sample is measured.

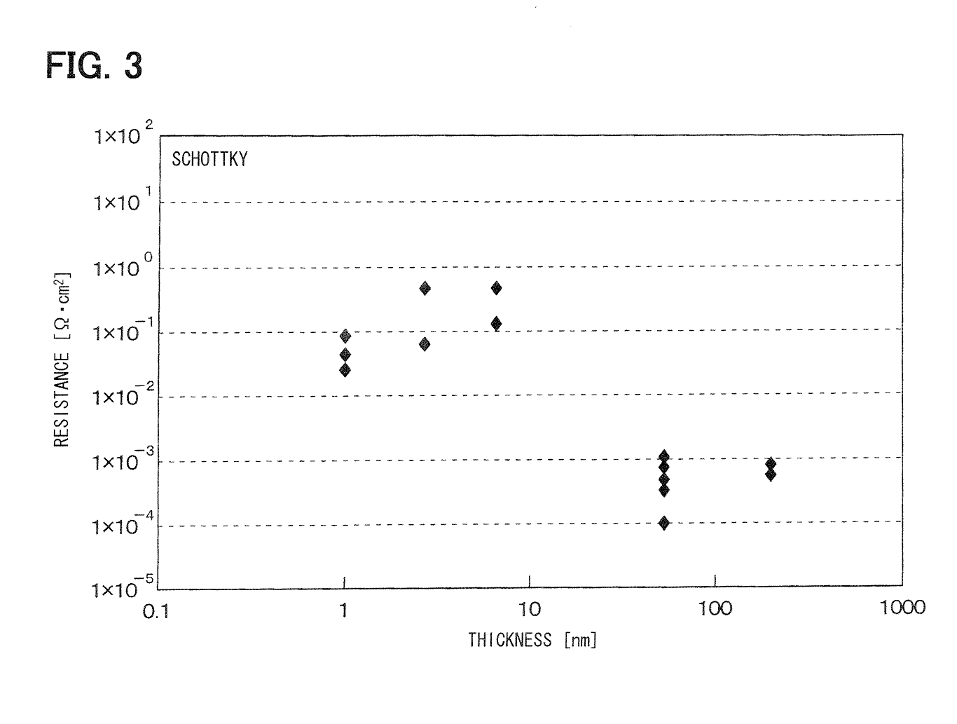

As shown in FIG. 3, in cases where the thickness of the amorphous layer 12 on the rear surface 1b of the n+ type substrate 1 is 0.5 nm, the drain electrode 11 has a Schottky junction with the n+ type substrate 1. In the present cases, Ni silicide is not detected in an Auger analysis.

In contrast, in cases where the thickness of the amorphous layer 12 on the rear surface 1b of the n+ type substrate 1 is greater than or equal to 1 nm, the resistance is reduced compared with the cases where the thickness of the amorphous layer 12 is 0.5 nm. In the cases where the thickness of the amorphous layer 12 is greater than 1 nm, Ni silicide is detected in the Auger analysis, and it is confirmed that the drain electrode 11 has an ohmic junction with the n+ type substrate 1. In particular, in cases where the thickness of the amorphous layer 12 on the rear surface 1b of the n+ type substrate 1 is 50 nm or 200 nm, an ohmic electrode having a low resistance of from 10⁻³ Ω·cm⁻² to 10⁻⁴ Ω·cm⁻² can be formed.

As a result, by setting the thickness of the amorphous layer 12 on the rear surface 1b of the n+ type substrate 1 to be greater than or equal to 1 nm, an ohmic electrode can be formed. However, from the experimental result shown in FIG. 3, in cases where the thickness of the amorphous layer 12 is less than 10 nm, the resistance may be high although the drain electrode 11 can have the ohmic junction. Furthermore, the thickness of the amorphous layer 12 may have a margin of plus or minus 20%. Thus, it is preferable that the lower limit of the thickness of the amorphous layer 12 is set to 10 nm with taking the margin of 20% into consideration in cases where the thickness of amorphous layer 12 is 8 nm. In cases where the thickness of the amorphous layer 12 is greater than 800 nm, the resistance is increased due to an unreacted part of the amorphous layer 12. Thus, it is preferable that the upper limit of the thickness of the amorphous layer 12 is se to be 800 nm.

Therefore, in the present embodiment, the thickness of the amorphous layer 12 on the rear surface 1b of the n+ type substrate 1 is from 10 nm to 800 nm. Furthermore, as shown in FIG. 3, in cases where the thickness of the amorphous layer 12 is from 50 nm to 200 nm, an ohmic junction having a low resistance can be formed.

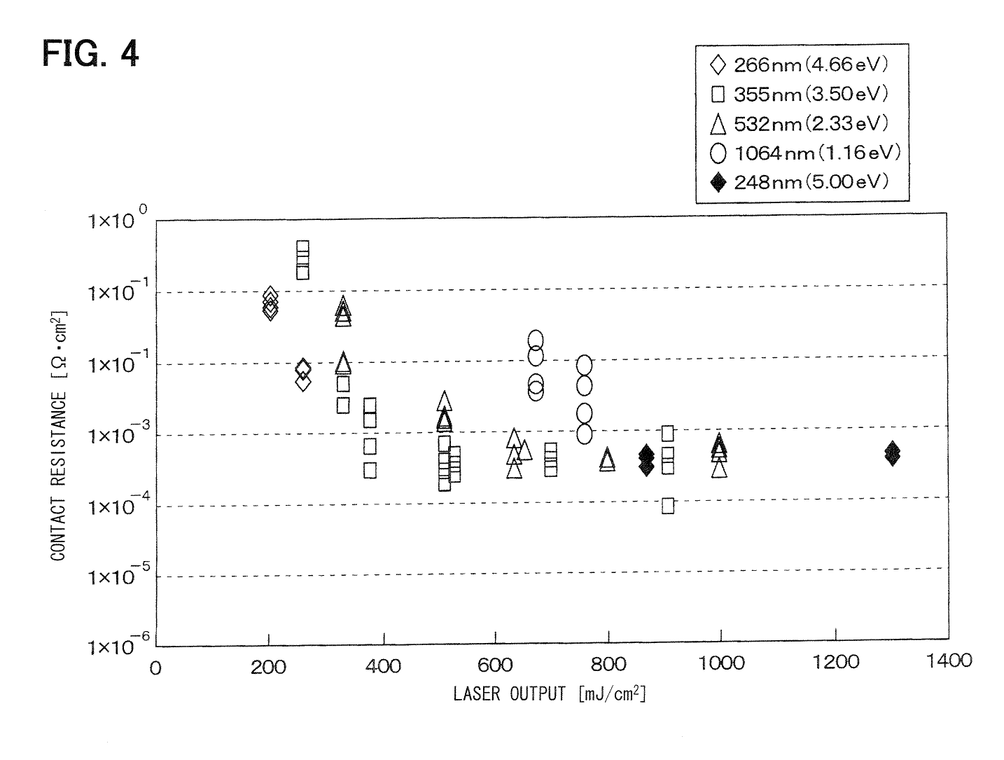

Next, the laser energy at the laser light irradiating process shown in FIG. 2C will be described. In an experiment by the inventors, in the laser irradiating process shown in FIG. 2C, an LD excited solid state laser having a fundamental wavelength of 1064 nm is used, a double wave (532 nm), a triple wave (355 nm), or a quadruple wave (266 nm) is generated through a wavelength conversion adapter, and the drain electrode 11 is formed with the laser light 50 having a wavelength of 1064 nm, 532 nm, 355 nm, or 266 nm. The laser light 50 has an intensity of from 200 mJ/cm² to 1000 mJ/cm². The resistance of the drain electrode 11 of each sample is measured and a result shown in FIG. 4 is obtained.

As shown in FIG. 4, at each of the wavelengths of 1064 nm, 532 nm, 355 nm, and 266 nm, the resistance is reduced with increase in the laser output. It is known that photon energy of light increases with decrease in wavelength of the light. Namely, the fundamental wave at 1064 nm has photon energy of 1.16 eV, the double wave at 532 nm has photon energy of 2.33 eV (double), the triple wave at 366 has photon energy of 3.50 eV (triple), and the quadruple wave at 266 nm has photon energy of 4.66 eV (quadruple).

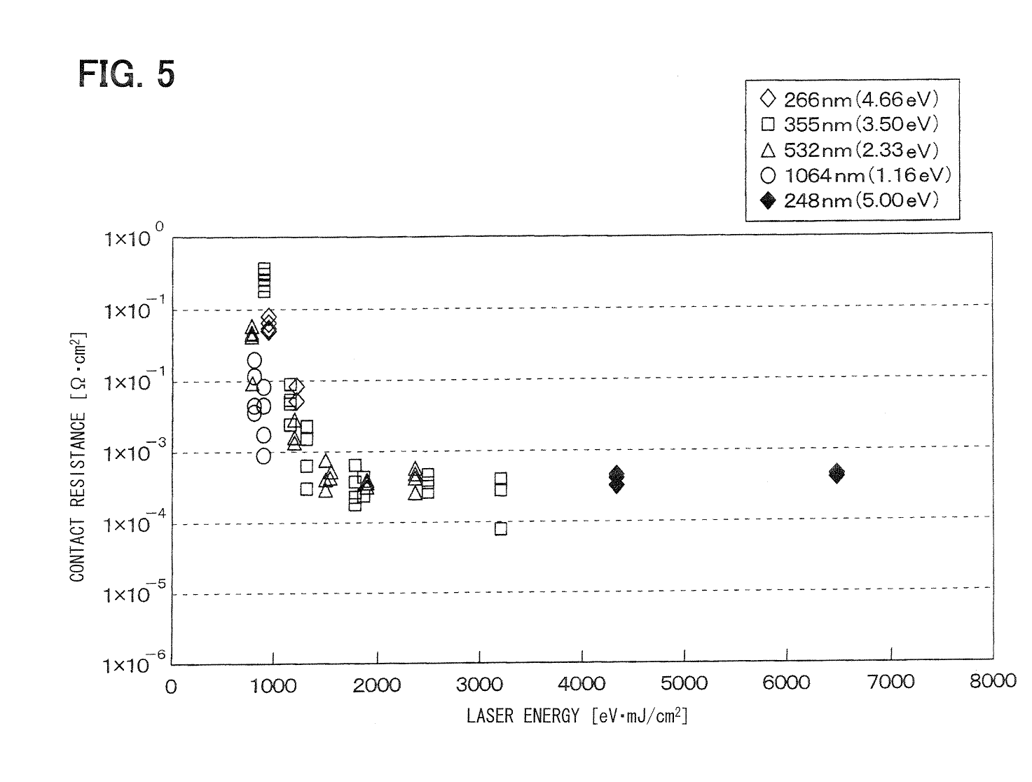

The inventors focus on the photon energy and show a relationship between the laser energy, that is, the product of the photon energy and the laser output and the resistance in FIG. 5.

As shown in FIG. 5, the resistances at each wavelength are on the same curve. In particular, when the product of the photon energy and the laser output is from 1000 eV·mJ/cm² to 8000 eV·mJ/cm², an ohmic electrode having a resistance of less than or equal to 10⁻³ Ω·cm⁻² can be formed. When the photon energy is too high, ablation or fusion may occur in the rear surface 1b of the n+ type substrate 1 by heat at the laser irradiation. Thus, it is preferable that the product of the photon energy and the laser output is less than or equal to 8000 eV·mJ/cm².

Therefore, in the present embodiment, the product of the photon energy and the laser output of the LD excited solid layer is set to be from 1000 eV·mJ/cm² to 8000 eV·mJ/cm².

Furthermore, in an experiment by the inventors, the drain electrode 11 is formed in each of a case where the amorphous layer 12 is not formed and a case where the amorphous layer 12 is formed by the method according to the present embodiment, and results of Auger analysis are compared with each other.

The metal layer 110 is removed by a Caro's cleaning from each of the sample in which the amorphous layer 12 is not formed and the sample in which the amorphous layer 12 is formed, and the rear surface 1b of the n+ type substrate 1 is analyzed by the Auger analysis.

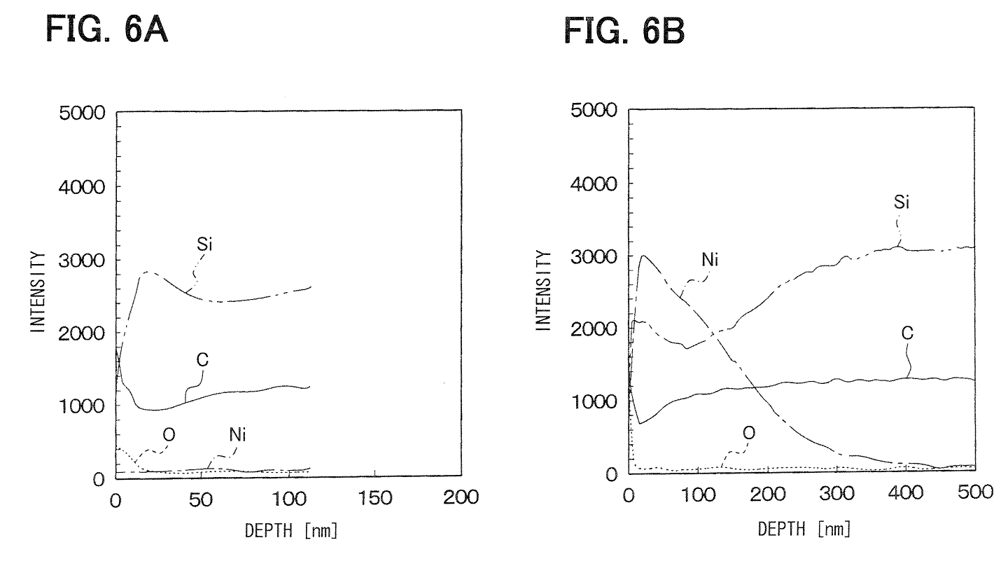

The result of sample in which the drain electrode 11 is formed without the amorphous layer 12 is shown in FIG. 6A, and the result of the sample in which the drain electrode 11 is formed with the amorphous layer 12 is shown in FIG. 6B. In each graph, a horizontal axis indicates a depth of the n+ type substrate 1 and a vertical axis indicates a detection intensity. When the detection intensity is high, the amount of detected element is large.

As shown in FIG. 6A, in the sample in which the drain electrode 11 is formed without the amorphous layer 12, carbon (C) and oxygen (O) which constitute the n+ type substrate 1 can be detected. However, Ni which constitutes the metal layer 110 cannot be detected. In other words, Ni does not exist in the n+ type substrate 1 and it is confirmed that Ni silicide is not formed.

However, as shown in FIG. 6B, in the sample in which the drain electrode 11 is formed with the amorphous layer 12, the amount of Ni decreases from the rear surface 1b of the n+ type substrate 1 in the depth direction. In other words, Ni silicide is formed from the rear surface 1b of the n+ type substrate 1 in the depth direction. This is because, when the amorphous layer 12 is formed, probability of transition of electrons without through phonon increases due to random nature of crystal and a light absorption coefficient increases, and thereby absorbed laser energy increases and Ni silicide is formed.

In this way, Ni silicide can be formed in the n+ type substrate 1 when the metal layer 110 is formed after the amorphous layer 12 is formed, the metal layer 110 is irradiated with the laser light, and thereby the drain electrode 11 is formed without a high-temperature treatment.

Even after the drain electrode 11 is formed on the rear surface 1b of the n+ type substrate 1 as described above, electrical property of elements formed above the front surface 1a of the n+ type substrate 1 does not change. Thus, the ohmic electrode (drain electrode 11) can be formed on the rear surface 1b without causing thermal damage to the n+ type substrate 1 having a front-surface electrode, in particular, to the front surface of the thinned n+ type substrate 1.

In this way, when the drain electrode 11 is formed by forming the amorphous layer 12 on the rear surface 1b of the n+ type substrate 1, forming the metal layer 110 on the amorphous layer 12, and irradiating the metal layer 110 with the laser light, the ohmic electrode having a low resistance can be formed.

As described above, in the present embodiment, after the element structure and the front electrode are formed on the front surface side of the n+ type substrate 1, the amorphous layer 12 is formed on the rear surface 1b of the n+ type substrate 1. The metal layer 110 is formed on the amorphous layer 12, and the metal layer 110 is irradiated with the laser light in a condition that the product of the photon energy and the laser output is from 1000 eV·mJ/cm² to 8000 eV·mJ/cm², and thereby the drain electrode 11 including the silicide layer 111 can be formed.

Accordingly, the drain electrode 11 including the silicide layer 111 can be formed on the n+ type substrate 1 without a high-temperature treatment. In other words, the drain electrode 11 can form the ohmic junction with the rear surface 1b of the n+ type substrate without causing thermal damage to the element structure formed on the front surface side of the n+ type substrate 1. Thus, the drain electrode 11 can be formed as an ohmic electrode at a low-temperature process without using an impurity-doped layer.

When the amorphous layer 12 is formed, the thickness of the amorphous layer 12 is set to be from 50 nm to 200 nm. Accordingly, an ohmic junction with a low resistance can be formed.

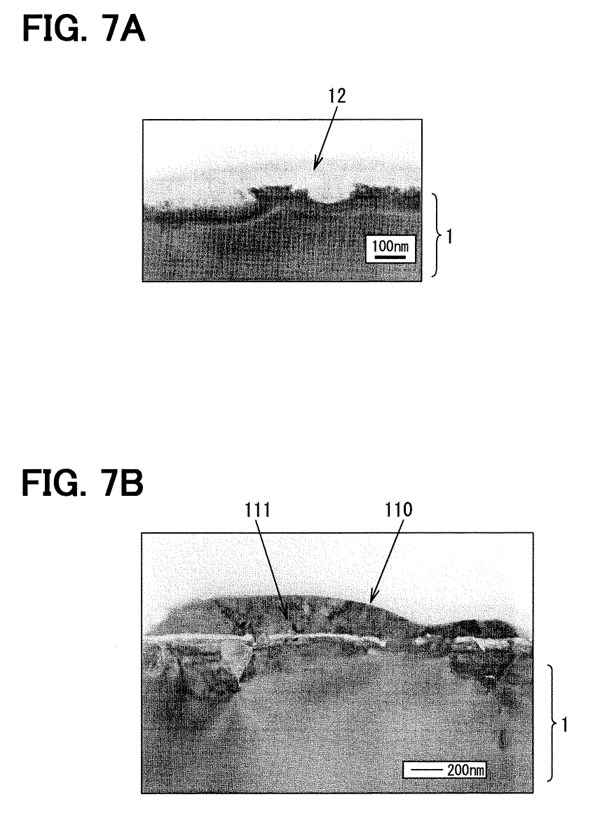

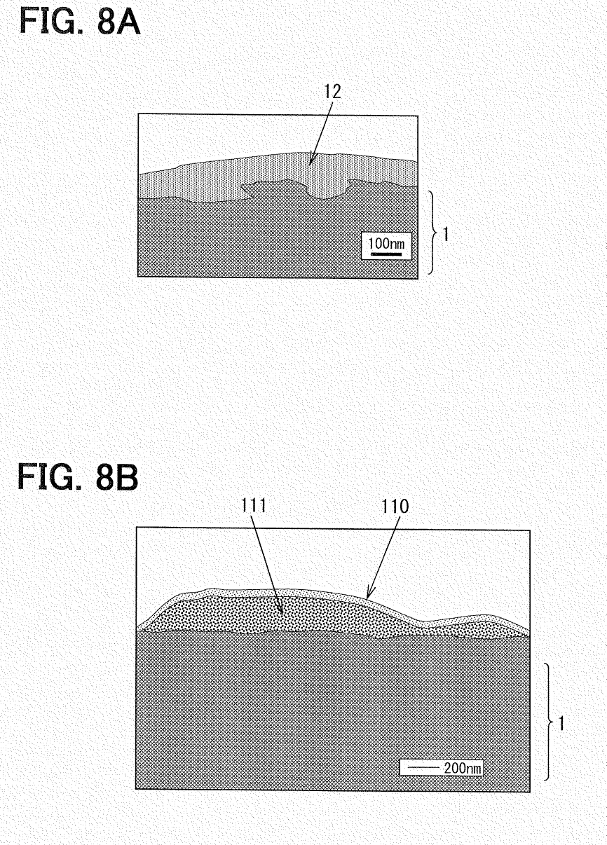

As reference, cross-sectional TEM images of samples in the process shown in FIG. 2A and the process shown in FIG. 2D are shown in FIG. 7A and FIG. 7B. The TEM images in FIG. 7A and FIG. 7B are illustrated in FIG. 8A and FIG. 8B, respectively. Before the laser anneal, the amorphous layer 12 having a convex shape is disposed on the rear surface 1b of the n+ type substrate 1 as shown in FIG. 7A, and the metal layer 110 is disposed on the amorphous layer 12. By the laser anneal, as shown in FIG. 7B, a part of the metal layer 110 reacts with the amorphous layer 12 to form the silicide layer 111. In this way, by forming the amorphous layer 12 on the rear surface 1b, the drain electrode 11 can be formed as the ohmic electrode at the low-temperature process without forming an impurity-doped layer having a high impurity concentration by ion implantation.

### Second Embodiment

A manufacturing method of a SiC semiconductor device according to a second embodiment will be described. In the present embodiment, a laser light for forming the silicide layer 111 is changed compared with the first embodiment, and other processes are similar to those of the first embodiment. Thus, only a process different from the first embodiment will be described.

In the present embodiment, a KrF excimer laser having a wavelength of 248 nm is used as the laser light. The silicide layer 111 is formed in the drain electrode 11 with the laser light of the KrF excimer laser having an intensity of 1300 mJ/cm². The laser light has photon energy of 5.00 eV. Thus, a product of the photon energy and the laser output is 6500 eV·mJ/cm². Also in this case, an ohmic electrode having a resistance of less than or equal to 10⁻³ Ω·cm⁻² can be formed. Thus, effects similar to the first embodiment can be achieved with the KrF excimer laser. Also when the KrF excimer laser is used, the metal layer 110 is irradiated with the laser light in a condition that a product of the photon energy and the laser output is from 1000 eV·mJ/cm² to 8000 eV·mJ/cm² in a manner similar to the first embodiment. Accordingly, the effects similar to the first embodiment can be achieved.

### Other Embodiments

In each of the above-described embodiments, the SiC semiconductor device includes the power MOSFET as an example. The above-described manufacturing methods can also be applied to a SiC semiconductor device that includes other element structure such as a diode and an IGBT.

In the process shown in FIG. 2A, the amorphous layer 12 is formed by grinding as an example. The amorphous layer 12 may also be formed by processing a surface portion of a rear surface of a semiconductor substrate with ion plasma, sputtering, or ion cluster plasma, depositing by a chemical vapor deposition method, or ion implantation. For example, also when the amorphous layer 12 is formed by processing the rear surface 1b of the n+ type substrate 1 with ion plasma and the drain electrode 11 is formed as shown in FIG. 2A to FIG. 2D, the drain electrode 11 can form an ohmic junction with the n+ type substrate 1. For example, the process with the ion plasma can be performed in a condition of CF₄: 15 sccm, O₂: 3 sccm, and power: 300 W or a condition of CHF₃: 50 sccm, Ar: 50 sccm, and power: 110 W. A process with Ar sputtering can be formed, for example, in a condition of Ar: 30 sccm and power: 300 W. The amorphous layer 12 may also be formed on the rear surface 1b by other method.

In the process shown in FIG. 2B, the metal layer 110 is formed by evaporation as an example. The metal layer 110 can also be formed by a CVD method, a coating method, or an electroplating method.

In the process shown in FIG. 2C, the LD excited solid state laser is used as the laser light as example. The laser light may also be a semiconductor laser, a YAG laser, or a gas laser.

As a material for the metal layer 110, Ti, Mo, or W which forms silicide may also be used instead of Ni. For example, when the metal layer 110 is made of Ti, the drain electrode 11 is formed through the processes shown in FIG. 2A to FIG. 2D, and the rear surface 1b of the n+ type substrate 1 is analyzed by an Auger analysis, generation of Ti silicide can be confirmed. In this way, also when the metal layer 110 is made of metal other than Ni which can form a silicide layer 111, the resistance of the drain electrode 11 can be reduced.

What is claimed is:

1. A manufacturing method of a silicon carbide semiconductor device including a semiconductor substrate and an electrode, wherein the semiconductor substrate is made of single crystal silicon carbide and has a first surface and a second surface opposite to each other, and the electrode forms an ohmic junction with the semiconductor substrate, the method comprising:
preparing the semiconductor substrate;
forming an amorphous layer on a portion of the semiconductor substrate where the electrode is to be formed;
forming a metal layer on the amorphous layer; and
forming the electrode including the metal layer and a silicide layer by irradiating the metal layer with a laser light in such a manner that a part of the metal layer reacts with the amorphous layer and forms the silicide layer.

2. The manufacturing method according to claim 1, wherein
the forming the amorphous layer includes forming the amorphous layer on the second surface of the semiconductor substrate in which a element structure is formed adjacent to the first surface.

3. The manufacturing method according to claim 1, wherein
the forming the amorphous layer includes forming the amorphous layer having a thickness of from 10 nm to 800 nm.

4. The manufacturing method according to claim 1, wherein
the forming the metal layer includes forming the metal layer including at least one of Ni, Ti, Mo, and W.

5. The manufacturing method according to claim 1, wherein
the forming the metal layer includes forming the metal layer having a thickness of greater than or equal to 10 nm.

6. The manufacturing method according to claim 1, wherein
the forming the electrode includes controlling a wavelength and a laser output of the laser light in such a manner that a product of photon energy and the laser output of the laser light is from 1000 eV·mJ/cm² to 8000 eV·mJ/cm².

7. The manufacturing method according to claim 1, wherein
the forming the electrode includes irradiating the metal layer with the laser light by one of a scanning method and a masking method.

8. The manufacturing method according to claim 1, wherein
the preparing the semiconductor substrate includes forming a element structure at a portion of the semiconductor substrate adjacent to the first surface and forming another electrode on the first surface, and
the forming the electrode is performed on the second surface of the semiconductor substrate after forming the element structure and the another electrode so that a vertical semiconductor device in which electric current flows in the element structure between the electrode on the second surface and the another electrode on the first surface is formed.

9. The manufacturing method according to claim 8, wherein
the preparing the semiconductor substrate further includes forming a protective layer that covers the another electrode after forming the another electrode and before forming the amorphous layer, the metal layer, and the electrode.
